(19) United States
(12) Patent Application Publication
(10) Pub. No.: US 2010/0255409 A1
(43) Pub. Date: Oct. 7, 2010

(54) Attenuated phase-shift photomasks, method of fabricating the same and method of fabricating semiconductor using the same

(76) Inventors: Man-Kyu Kang, Yuseong-gu (KR); Ju-Mi Bang, Cheonan-si (KR); Seong-Yoon Kim, Yongin-si (KR); Jung-Hyun Lee, Seoul (KR)

Correspondence Address: LEE & MORSE, P.C., 3141 FAIRVIEW PARK DRIVE, SUITE 500, FALLS CHURCH, VA, 22042, US

(21) Appl. No.: 12/662,019

(22) Filed: Mar. 29, 2010

(30) Foreign Application Priority Data
Apr. 1, 2009 (KR) 10-2009-0028197

(51) Int. Cl. G03F 1/00; G03F 7/20

(52) U.S. Cl. 430/5; 430/319

(57) ABSTRACT

A method of fabricating an attenuated phase-shift photomask includes forming a phase-shift material layer on a photomask substrate, forming a light opaque layer on the phase-shift material layer, forming a first resist pattern on the light opaque layer to selectively expose a pattern region, etching the light opaque layer using the first resist pattern as an etch mask, such that a first light opaque pattern layer is formed to selectively expose the phase-shift material layer, removing the first resist pattern, forming a second resist pattern on the light opaque layer, such that a cell pattern block in the pattern region is selectively exposed, and etching the exposed phase-shift material layer using the first light opaque pattern layer as an etch mask to form a phase-shift material pattern layer selectively exposing a top surface of the photomask substrate.

### BACKGROUND

1. Field

Example embodiments relate to an attenuated phase-shift photomask, a method of fabricating the same, and a method of fabricating a semiconductor device using the same.

2. Description of Related Art

Photolithography techniques for forming patterns may be essential to fabrication of semiconductor devices which continue to become highly integrated. Photolithography techniques may depend on various process parameters, e.g., a photomask. For example, formation of fine patterns may involve forming a high-quality photomask to perform a subsequent photolithography process without difficulty. Therefore, a photomask, e.g., an attenuated phase-shift photomask, fabrication technique may be very important.

### SUMMARY

Embodiments are therefore directed to an attenuated phase-shift photomask, a method of fabricating the same, and a method of fabricating a semiconductor device using the same, which substantially overcome one or more of the problems due to the limitations and disadvantages of the related art.

It is therefore a feature of an embodiment to provide an attenuated phase-shift photomask.

It is therefore another feature of an embodiment to provide a method of fabricating an attenuated phase-shift photomask.

It is yet another feature of an embodiment to provide a method of fabricating a semiconductor device using an attenuated phase-shift photomask.

At least one of the above and other features and advantages may be realized by providing an attenuated phase-shift photomask, including a phase-shift pattern layer disposed on a photomask substrate. The phase-shift pattern layer includes a pattern region disposed in the center of the photomask substrate and an opaque region disposed in an edge of the photomask substrate. The pattern region includes a cell pattern block having optical patterns, a rim region surrounding the cell pattern block in a rim type, and a peripheral region surrounding the rim region. The rim region does not include optical patterns.

The method may further include, after removing the second resist pattern, removing the first light opaque pattern layer from the pattern region to form a second light opaque pattern layer outside the pattern region. Forming the second light opaque pattern layer may include forming a third resist pattern on the first light opaque pattern layer, such that the pattern region is exposed, and removing the first light opaque pattern layer exposed in the pattern region using the third resist pattern as an etch mask. The method may further include removing the first light opaque pattern layer from the cell pattern block to form a third light opaque pattern layer. Removing the first light opaque pattern layer from the cell pattern block may include removing the first light opaque pattern layer exposed in the cell pattern block using the second resist pattern as an etch mask. The pattern region may be formed on the photomask substrate to include a rim region surrounding the cell pattern block, the rim region being formed between a boundary line of the pattern region and a boundary line of the cell pattern block to surround the cell pattern block in a rim type. Etching the light opaque layer may include removing portions of the light opaque layer from the rim region to expose the phase-shift material layer, and forming the second resist pattern may include covering the phase-shift material layer in the rim region, such that the rim region includes the phase-shift material pattern layer. The rim region may be formed to have a width of about 200 μm to about 500 μm. The method may further include forming a resist pattern exposing a peripheral region, the peripheral region being in the pattern region and having a boundary line between a boundary line of the pattern region and a boundary line of the cell pattern block, and removing the first light opaque pattern layer from the peripheral region.

At least one of the above and other features and advantages may also be realized by providing a method of fabricating an attenuated phase-shift photomask, including forming a phase-shift material layer on a photomask substrate, forming a light opaque layer on the phase-shift material layer, forming a first resist pattern on the light opaque layer to selectively expose a pattern region, etching the light opaque layer exposed in the pattern region using the first resist pattern as an etch mask, and forming a first light opaque pattern layer selectively exposing the phase-shift material layer, removing the first resist pattern, forming a second resist pattern on the light opaque layer, the first light opaque pattern layer, and the selectively exposed phase-shift material layer to selectively expose a cell pattern block included in the pattern region, etching the selectively exposed phase-shift material layer using the first light opaque pattern layer, which is exposed in the cell pattern block, as an etch mask, and forming a phase-shift material pattern layer selectively exposing a top surface of the photomask substrate, and removing the second resist patter.

At least one of the above and other features and advantages may also be realized by providing a method of fabricating a semiconductor, including loading a wafer into a photolithography system having an attenuated phase-shift photomask, the wafer having a material layer and a photoresist layer thereon, irradiating the photoresist layer using UV light, developing the photoresist layer to form a photoresist pattern, patterning the material layer to form a material pattern using the photoresist pattern as a patterning mask, removing the photoresist pattern, and cleaning the wafer, wherein the attenuated phase-shift photomask is fabricated by a method of fabricating attenuated phase-shift photomasks comprising, forming a phase-shift material layer on a photomask substrate, forming a light opaque layer on the phase-shift material layer, forming a first resist pattern on the light opaque layer to selectively expose a pattern region, etching the light opaque layer exposed in the pattern region using the first resist pattern as an etch mask, and forming a first light opaque pattern layer selectively exposing the phase-shift material layer, removing the first resist pattern, forming a second resist pattern on the light opaque layer, the first light opaque pattern layer, and the selectively exposed phase-shift material layer to selectively expose a cell pattern block included in the pattern region, etching the selectively exposed phase-shift material layer using the first light opaque pattern layer, which is exposed in the cell pattern block, as an etch mask, and forming a phase-shift material pattern layer selectively exposing a top surface of the photomask substrate, and removing the second resist pattern.

At least one of the above and other features and advantages may also be realized by providing a method of fabricating a semiconductor, including loading a wafer into a photolithography system having an attenuated phase-shift photomask, the wafer having a material layer and a photoresist layer thereon, irradiating the photoresist layer using UV light, developing the photoresist layer to form a photoresist pattern, patterning the material layer to form a material pattern using the photoresist pattern as a patterning mask, removing the photoresist pattern, and cleaning the wafer, wherein the attenuated phase-shift photomask includes a phase-shift pattern layer disposed on a photomask substrate, wherein the phase-shift pattern layer includes a pattern region disposed in the center of the photomask substrate and an opaque region disposed in an edge of the photomask substrate, wherein the pattern region includes a cell pattern block having optical patterns, a rim region surrounding the cell pattern block in a rim type, and a peripheral region surrounding the rim region, and wherein the rim region does not include optical patterns.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1A through 6A illustrate plan views of attenuated phase-shift photomasks according to example embodiments;

FIGS. 1B through 6B illustrate longitudinal sectional views taken along respective lines 1B-1B′, 2B-2B′, 3B-3B′, 4B-4B′, 5B-5B′, and 6B-6B′ of FIGS. 1A through 6A;

FIGS. 7A through 7N illustrate longitudinal sectional views of methods of fabricating attenuated phase-shift photomasks according to example embodiments;

FIG. 8 illustrates a flow chart of steps of fabricating a semiconductor according to example embodiments; and

FIGS. 9A to 9D illustrate processes of fabricating a semiconductor using an attenuated phase-shift mask according to example embodiments.

### DETAILED DESCRIPTION

Korean Patent Application No. 10-2009-0028197, filed on Apr. 1, 2009, in the Korean Intellectual Property Office, and entitled: “Attenuated Phase-Shift Photomasks, Method of Fabricating the Same and Method of Fabricating Semiconductor Using the Same,” is incorporated by reference herein in its entirety.

Various example embodiments will now be described more fully with reference to the accompanying drawings in which some example embodiments are shown. This inventive concept may, however, be embodied in different forms and should not be construed as limited to the embodiments set forth herein. Rather, these embodiments are provided so that this disclosure is thorough and complete and fully conveys the scope of the inventive concept to one skilled in the art. In the drawings, the thicknesses of layers and regions may be exaggerated for clarity. Like numbers refer to like elements throughout.

It will also be understood that when a layer or element is referred to as being “on” another layer or substrate, it can be directly on the other layer or substrate, or intervening layers may also be present. In addition, it will also be understood that when a layer or element is referred to as being “between” two layers or elements, it can be the only layer/element between the two layers/elements, or one or more intervening layers/elements may also be present.

In the present specification, a phase of light transmitted through a phase-shift material layer or a phase-shift pattern layer may be shifted about 90° to about 270°, e.g., about 180°. Further, in the present specification, the term “optical patterns” refers to stepped or mesa-shaped patterns formed of a phase-shift material on a photomask substrate of an attenuated phase-shift photomask.

In the present specification, it will also be understood that terms requiring a standard object have relative standards for a cell pattern block and a peripheral region, unless expressly so defined herein. In addition, in the present specification, “light” may refer to a light source used in a photolithography process, i.e., light with a specific wavelength. Since light with one of various wavelength ranges is selected according to a photolithography process, defining the wavelength of light may be insignificant. For reference, experiments for embodying the present inventive concept were conducted using an ArF light source with a wavelength of 193 nm and a KrF light source with a wavelength of 248 nm.

In advanced semiconductor technology, forming fine patterns may include using various photomasks and ensuring the uniformity of the fine patterns. In general, the uniformity of patterns may be affected and controlled by an electronic beam (e-beam) exposure process of forming and patterning a photoresist layer or e-beam resist layer on a photomask, a development process of developing an exposed resist layer, and an etching process of forming a patterning mask. However, pattern uniformity may be greatly degraded at a boundary region between pattern regions having optical patterns, e.g., due to non-uniformity of patterning mask patterns for patterning a phase-shift material layer. The degradation of pattern uniformity refers to an increased difference between the greatest and smallest widths of the optical patterns. Therefore, according to example embodiments, an attenuated phase-shift photomask and a method of fabricating the same according to example embodiments may improve pattern uniformity at a boundary region between pattern regions having patterns with different shapes, e.g., via a method for removing or lessening an influence of the density of patterns on the development process.

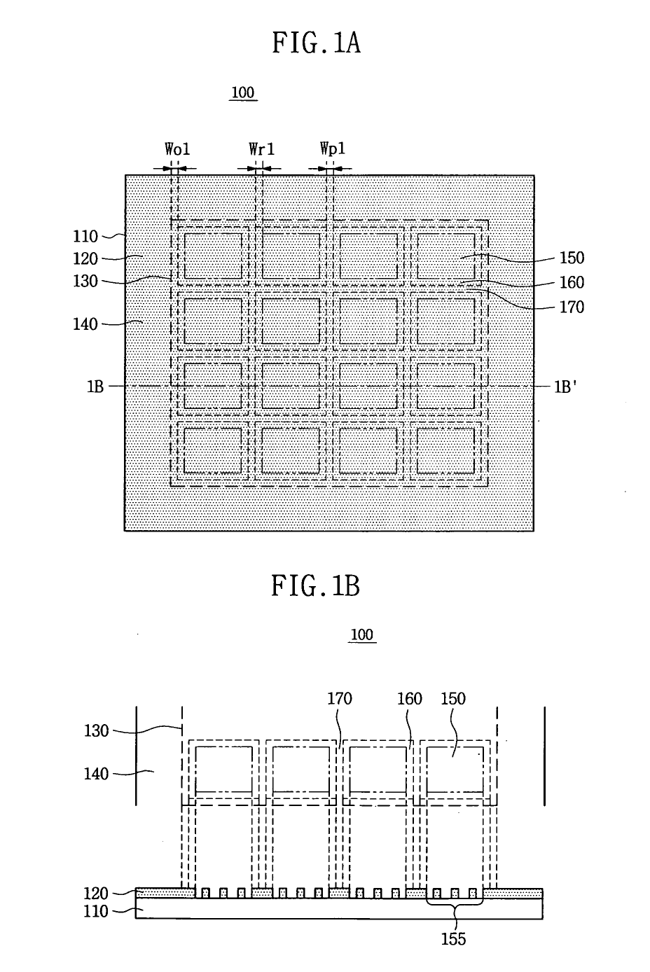

FIG. 1A illustrates a plan view of an attenuated phase-shift photomask according to a first example embodiment, and FIG. 1B illustrates a longitudinal sectional view taken along line 1B-1B′ of FIG. 1A. FIGS. 1A and 1B simply illustrate the technical scope of the present example embodiment for brevity. Thus, an actual attenuated phase-shift photomask may be formed in a different shape and ratio than in the drawings of the present specification without departing from the technical spirit and scope of the present example embodiment. The present example embodiment will be fully understood by one skilled in the art with reference to the present specification.

Referring to FIGS. 1A and 1B, an attenuated phase-shift photomask 100 according to the present example embodiment may include a photomask substrate 110, and a pattern region 130 and an opaque region 140, which are formed on the photomask substrate 110. Each of the pattern region 130 and the opaque region 140 may include a phase-shift material layer 120. The pattern region 130 may include at least one cell pattern block 150, at least one rim region 160, and at least one peripheral region 170. The cell pattern block 150 may include optical patterns 155. The optical patterns 155 may be formed of a phase-shift material. That is, the phase-shift material layer 120 may be patterned to form the optical patterns 155 in the cell pattern block 150. No optical patterns 155 may be formed in the rim region 160. Although other optical patterns may be formed in the peripheral region 170, the optical patterns in the peripheral region 170 may be formed to a much larger size or a much lower density than the optical patterns 155 in the cell pattern block 150.

The phase-shift material layer 120 may be semitransparent. It is noted that the semitransparency of the phase-shift material layer 120 is different from absence of the optical patterns 155. In other words, the optical patterns 155 refer to patterns selectively formed on the transparent photomask substrate 110 using a phase-shift material. Thus, the absence of the optical patterns 155 may refer to exposing the surface of the transparent photomask substrate 110 or to completely covering the surface of the photomask substrate 110 with the phase-shift material layer 120. Therefore, presence of the optical patterns 155 on the transparent photomask substrate 110 may refer to intermingling the surface of the transparent photomask substrate 110 with the phase-shift material layer 120.

The photomask substrate 110 may be formed of a transparent inorganic material, e.g., quartz or glass. The phase-shift material layer 120 in which the optical patterns 155 are wholly formed may be formed on the surface of the photomask substrate 110.

The phase-shift material layer 120 may be in the pattern region 130 and the opaque region 140. The phase-shift material layer 120 may be formed of an inorganic semitransparent material including molybdenum (Mo) and silicon (Si). The semitransparent material means that an optical transmittance through the phase-shift material layer 120 is other than zero (0). In other words, when the phase-shift material layer 120 is semitransparent, the phase-shift material layer 120 may have some optical transmittance, e.g., of about 1% to about 50%, and may transmit some light.

The optical transmittance of the phase-shift material layer 120 may be variously determined according to the use of the attenuated phase-shift photomask 100. For example, the phase-shift material layer 120 may be formed to have an optical transmittance of about 5% to about 30%. Since a thickness of the phase-shift material layer 120 is closely related to the optical transmittance thereof, the thickness of the phase-shift material layer 120 may be determined according to a type of light source used in a photolithography process, and the optical transmittance of the phase-shift material layer 120 may be varied according to the thickness thereof. In order to separately control the optical transmittance of the phase-shift material layer 120, a composition ratio of the phase-shift material layer 120 may be adjusted by adding additional materials, e.g., oxygen and/or nitrogen, to the phase-shift material layer 120. For example, the phase-shift material layer 120 may be formed of a molybdenum-silicon (MoSi) layer, a molybdenum-silicon oxide (MoSiO) layer, a molybdenum-silicon nitride (MoSiN) layer, a molybdenum-silicon oxy-nitride (MoSiON) layer, or an inorganic material containing Mo and Si to which other materials are added.

The pattern region 130 may be formed, e.g., in a rectangular shape, in the center of the photomask substrate 110, and may include the cell pattern block 150 and the rim region 160. The pattern region 130 may be a region where a single semiconductor chip or a plurality of semiconductor chips will be formed. More specifically, although a single semiconductor chip pattern may be formed on one attenuated phase-shift photomask 100, a plurality of semiconductor chip patterns may be formed on the one attenuated phase-shift photomask 100 to improve productivity. For example, in FIG. 1A, the pattern region 130 may be a region where a single semiconductor chip will be formed or each of the cell pattern blocks 150 may be a region where a single semiconductor chip will be formed.

The opaque region 140, where the optical patterns 155 are not formed, may be disposed to surround the pattern region 130 outside the photomask substrate 110. However, an alignment key for aligning the attenuated phase-shift photomask 100, a photomask identifier (ID), and a bar code may be formed in the opaque region 140.

The cell pattern block 150 may include the optical patterns 155 for transferring a semiconductor chip pattern on a semiconductor wafer. It will be understood that the cell pattern block 150 refers to a region of a semiconductor chip where patterns with the same shape are repetitively formed. For example, in the case of a memory semiconductor device, the cell pattern block 150 may refer to a region where storage patterns, e.g., capacitors, transistors, or strings, are formed. In the case of an image sensor, e.g., a CMOS image sensor (CIS) or a charge coupled device (CCD), the cell pattern block 150 may refer to an active pixel sensor (APS) array region. In the case of a display device, e.g., a liquid crystal display (LCD), the cell pattern block 150 may refer to a display cell region. In the case of a logic device, the cell pattern block 150 may refer to a region where transistors with the same standard or size are crowded. Also, the cell pattern block 150 may include a plurality of unit cell blocks (not shown). More specifically, the cell pattern block 150 may include a plurality of unit cell blocks arranged in rows and columns in equal number to an integer multiple of 2. For example, when the cell pattern block 150 has a processing capacity of 1 Mb, four unit cell blocks, each of which has a processing capacity of 256 kb, may be arranged in two rows and two columns to constitute a single cell pattern block 150. It is noted that boundary regions may be present between the unit cell blocks. The boundary regions may be typically referred to as core regions in which semiconductor patterns may be formed. That is, the optical patterns may be formed on the attenuated phase-shift photomask 100.

The rim region 160 may be formed to surround the cell pattern block 150, e.g., each rim region 160 may surround a single cell pattern block 150 to separate adjacent cell pattern blocks 150 from each other. The rim region 160 may be formed in a rim type, e.g., have a frame shape around the cell pattern block 150. The rim region 160 may not include the optical patterns 155, and may expose the phase-shift material layer 120. The rim region 160 may be formed to a width Wr1, e.g., about 200 μm to about 500 μm. The rim region 160 may extend from an outermost boundary line of the cell pattern block 150 toward the peripheral region 170. That is, the rim region 160 may extend from each outermost side line of the cell pattern block 150 toward a respective peripheral region 170 to define the width Wr1 and surround the cell pattern block 150. If a size of the cell pattern block 150 is reduced, the rim region 160 may extend between the reduced cell pattern block 150 and the peripheral region 170 to have a large area. The size of each of the cell pattern blocks 150 and the size of each of the optical patterns 155 may be variously varied according to the type of a desired semiconductor device. Therefore, numerically defining the size of each of the cell pattern blocks 150 and the size of each of the optical patterns 155 may be insignificant. However, defining the width Wr of the rim region 160 may be significant because the presence of the rim region 160 may improve uniformity of the optical patterns 155 in the cell pattern block 150. In particular, the uniformity of the optical patterns 155 associated with the rim region 160 depends on the density of e-beams irrespective of a desired shape or size of the optical patterns 155. Therefore, the uniformity of the optical patterns 155 may be improved by maintaining the density of e-beams uniform during an e-beam exposure process.

In detail, each shot of e-beam irradiation may have a circular or polygonal shape. An e-beam exposure process may involve irradiating an infinite number of e-beam shots onto a photoresist or an e-beam resist. A single e-beam shot may be reflected or scattered and affect other neighboring beam shots. For example, a single e-beam shot may affect a region with a width of several tens of μm in all directions, and may also affect a wider region according to irradiation energy. Further, a difference in e-beam exposure energy may lead to an amplified difference in a resist development process because the development process may affect or be affected by peripheral patterns. That is, pattern uniformity may be degraded in an edge portion of a conventional cell pattern block even during a development process due to a difference in e-beam exposure energy. Also, an etching process may produce about the same results as the development process. Therefore, degradation of pattern uniformity may occur due to the density of patterns. Thus, in order to improve the pattern uniformity in the edge portion of the cell pattern block 150 according to example embodiments, it may be necessary to prevent a reduction in density of the optical patterns 155 in the edge portion of the cell pattern block 150. To do this, for instance, resist may be exposed to obtain a pattern with a greater size than the size of the designed cell pattern block 150, and subsequent processes may be performed. The exposed pattern should have the same shape as the optical patterns 155 exposed in the cell pattern block 150. When the exposed pattern has a different shape from the optical patterns 155, the density of patterns may differ. However, the optical patterns 155 may be formed only in the designed cell pattern block 150. A detailed description of the e-beam exposure process will be provided later along with methods of fabricating attenuated phase-shift photomasks according to various example embodiments.

The peripheral region 170 may be formed to surround the rim region 160. The peripheral regions 170 may be formed at a wide range of intervals according to the layout of the cell pattern block 150. The peripheral region 170 also may not include the optical patterns 155, and may be covered with the phase-shift material layer 120. Alternatively, unlike the crowded optical patterns 155 formed in the cell pattern block 150, the peripheral region 170 may include large-sized optical patterns at sufficiently large intervals and at a low density. In other words, the peripheral region 170 may include optical patterns formed at a much lower density than the optical patterns 155 formed in the cell pattern block 150. For example, when a plurality of cell pattern blocks 150 constitutes a single semiconductor chip, the peripheral region 170 may be a peripheral circuit region of the semiconductor chip. Since peripheral circuits function to issue commands and control cell circuits, the peripheral circuits may be configured to large sizes at a low density. In this case, optical patterns for forming semiconductor patterns may be formed in the peripheral region 170. The peripheral region 170 may have a width Wp1, i.e., as measured between two adjacent rim regions 160, or a width Wo1, i.e., as measured between a rim region 160 and the opaque region 140.

Referring again to FIG. 1B, the attenuate phase-shift photomask 100 according to the present example embodiment may include the photomask substrate 110 and the phase-shift material layer 120 formed on the photomask substrate 110. The phase-shift material layer 120 may include the pattern regions 130 and the opaque regions 140. The pattern regions 130 may include at least two cell pattern blocks 150, at least two rim regions 160, and at least two peripheral regions 170. The cell pattern block 150 may include the optical patterns 155.

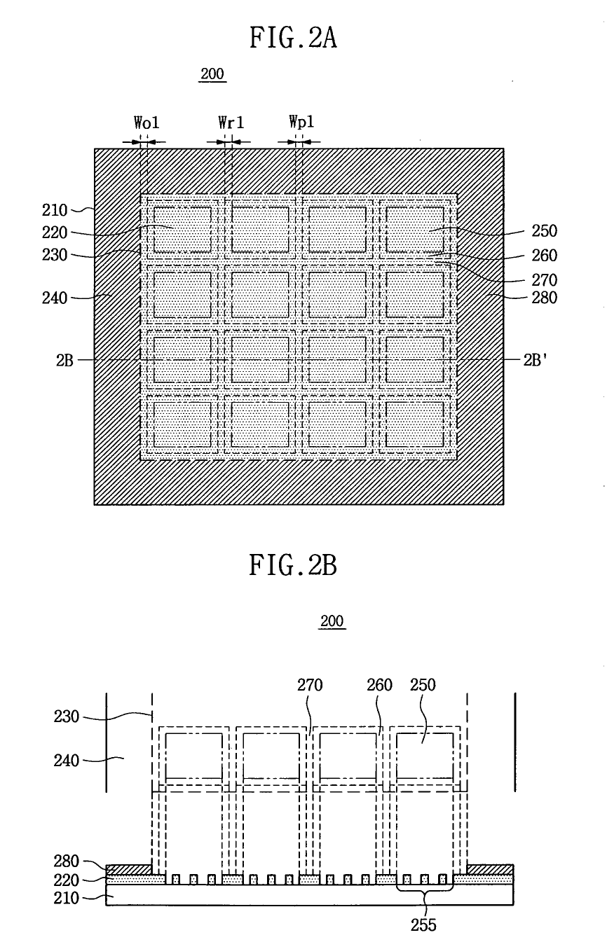

FIG. 2A illustrates a plan view of an attenuated phase-shift photomask according to a second example embodiment. FIG. 2B illustrates a longitudinal sectional view taken along line 2B-2B′ of FIG. 2A.

Referring to FIGS. 2A and 2B, an attenuated phase-shift photomask 200 according to the second example embodiment may include a photomask substrate 210, and a pattern region 230 and an opaque region 240 formed on the photomask substrate 210. Each of the pattern region 230 and the opaque region 240 may include a phase-shift material layer 220, and the opaque region 240 may further include a light opaque pattern layer 280. The pattern region 230 may include at least two cell pattern blocks 250, at least two rim regions 260, and at least two peripheral regions 270. The cell pattern block 250 may include optical patterns 255, which may be formed of a phase-shift material. A detailed description of the components of FIGS. 2A and 2B will be understood with reference to FIGS. 1A and 1B and the description of the components of FIGS. 1A and 1B.

The light opaque pattern layer 280 may be formed on the entire surface or almost the entire surface of the opaque region 240. The light opaque pattern layer 280 may be opaque to light, and may be formed of, e.g., chromium (Cr), aluminum (Al), Mo, a refractory metal, or an alloy thereof. For example, the light opaque pattern layer 280 may be formed of Cr. An alignment key, a mask ID, and a bar code may be formed even on the light opaque pattern layer 280. The light opaque pattern layer 280 may be further formed even on portions of the peripheral regions 270.

Referring to FIG. 2B, the attenuated phase-shift photomask 200 according to the second example embodiment may include the photomask substrate 210, the phase-shift material layer 220 formed on the photomask substrate 210, and the light opaque pattern layer 280 formed on the phase-shift material layer 220. The phase-shift material layer 220 may be formed and exposed in the pattern region 230, and the light opaque pattern layer 280 may be formed in the opaque region 240. The pattern region 230 may include at least two cell pattern blocks 250, at least two rim regions 260, and at least two peripheral regions 270. The cell pattern block 230 may include the optical patterns 255.

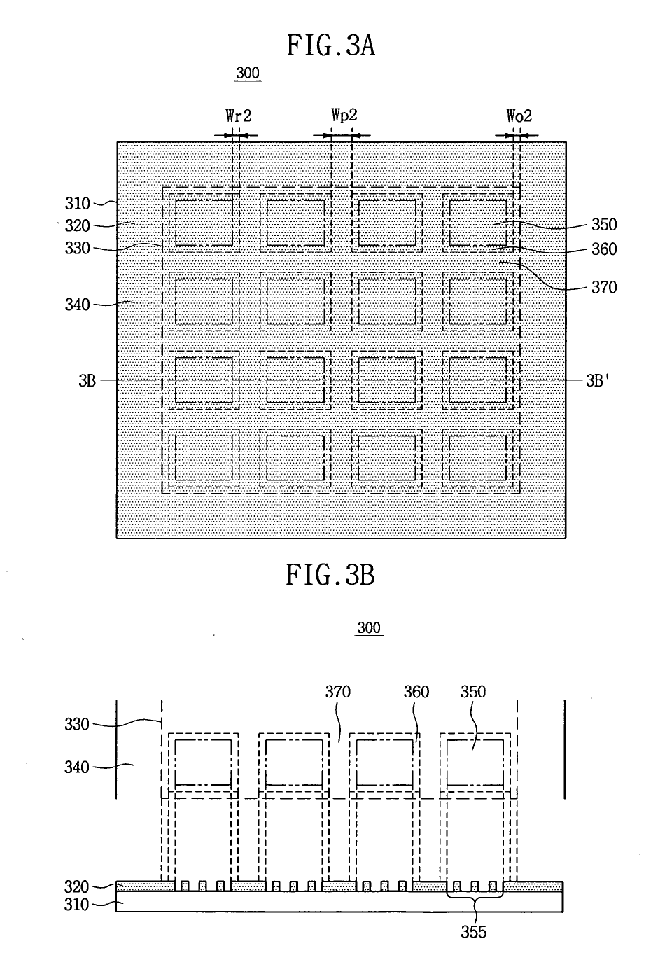

FIG. 3A illustrates a plan view of an attenuated phase-shift photomask according to a third example embodiment. FIG. 3B illustrates a longitudinal sectional view taken along line 3B-3B′ of FIG. 3A.

Referring to FIGS. 3A and 3B, an attenuated phase-shift photomask 300 according to the third example embodiment may include a photomask substrate 310, and a pattern region 330 and an opaque region 340 formed on the photomask substrate 310. Each of the pattern region 330 and the opaque region 340 may include a phase-shift material layer 320, and the pattern region 330 may include at least two cell pattern blocks 350 and at least two rim regions 360. The cell pattern block 350 may include optical patterns 355. The optical patterns 355 may be formed of a phase-shift material. The components of FIGS. 3A and 3B will be understood with reference to FIGS. 1A through 2B and the description of the components of FIGS. 1A through 2B, and thus a detailed description thereof will be omitted. In the attenuated phase-shift photomask 300 according to the present example embodiment, a width Wp2 of a peripheral region 370 interposed between two adjacent rim regions 360 may be greater than a width Wo2 of a peripheral region 370 interposed between the rim region 360 and the opaque region 340. The region 360 may have a width Wr2.

Referring to FIG. 3B, the attenuated phase-shift photomask 300 according to the third example embodiment may include the photomask 310 and the phase-shift material layer 320 formed on the photomask substrate 310. The pattern region 330 may include at least two cell pattern blocks 350 and at least two rim regions 360. The cell pattern block 350 may include the optical patterns 355.

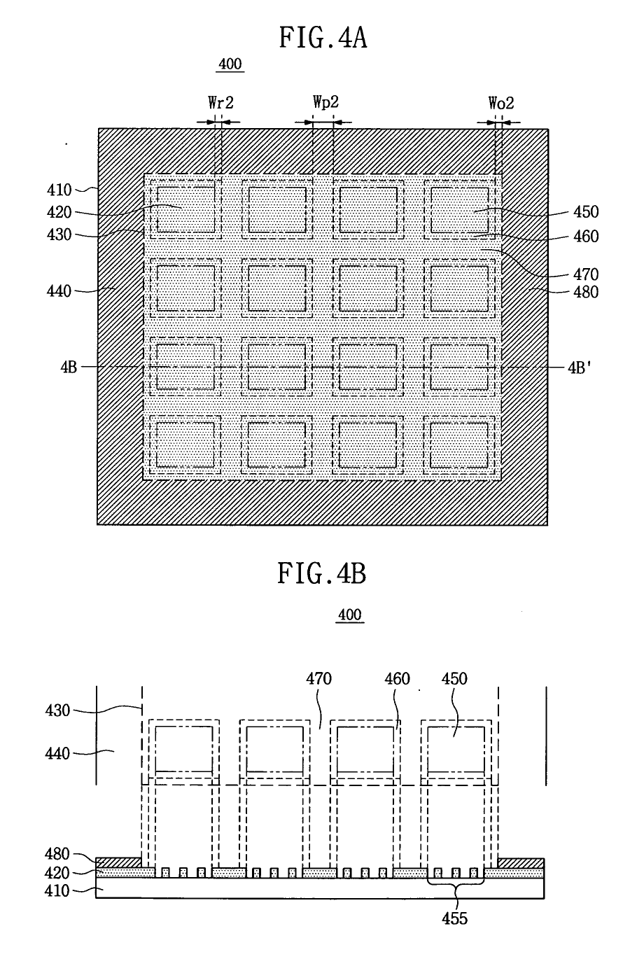

FIG. 4A illustrates a plan view of an attenuated phase-shift photomask according to a fourth example embodiment. FIG. 4B illustrates a longitudinal sectional view taken along line 4B-4B′ of FIG. 4A.

Referring to FIGS. 4A and 4B, an attenuated phase-shift photomask 400 according to the fourth example embodiment may include a photomask substrate 410, and a pattern region 430 and an opaque region 440 formed on the photomask substrate 410. Each of the pattern region 430 and the opaque region 440 may include a phase-shift material layer 420, and the opaque region 440 may further include a light opaque pattern layer 480. The pattern region 430 may include at least two cell pattern blocks 450, at least two rim regions 460, and at least two peripheral regions 470. The cell pattern block 450 may include optical patterns 455, which may be formed of a phase-shift material. A detailed description of the components of FIGS. 4A and 4B will be understood with reference to FIGS. 1A through 3B and the description of the components of FIGS. 1A through 3B. Like the attenuated photo-shift photomask 300 of FIGS. 3A and 3B, the attenuated phase-shift photomask 400 according to the present example embodiment may also be formed to have the width Wp2 interposed between the rim regions 460 greater than the width Wo2 interposed between the rim region 460 and the opaque region 440. The light opaque pattern layer 480 may be substantially the same as the light opaque pattern layer 280 described previously with reference to FIGS. 2A-2B.

Referring to FIG. 4B, the attenuated phase-shift photomask 400 may include the photomask substrate 410, the phase-shift material layer 420 formed on the photomask substrate 410, and the light opaque material layer 480 formed on the phase-shift material layer 420. The phase-shift material layer 420 may be formed and exposed in the pattern region 430, and the light opaque pattern layer 480 may be formed in the opaque region 440. The pattern region 430 may include at least two cell pattern blocks 450, at least two rim regions 460, and at least two peripheral regions 470. The cell pattern block 450 may include the optical patterns 455.

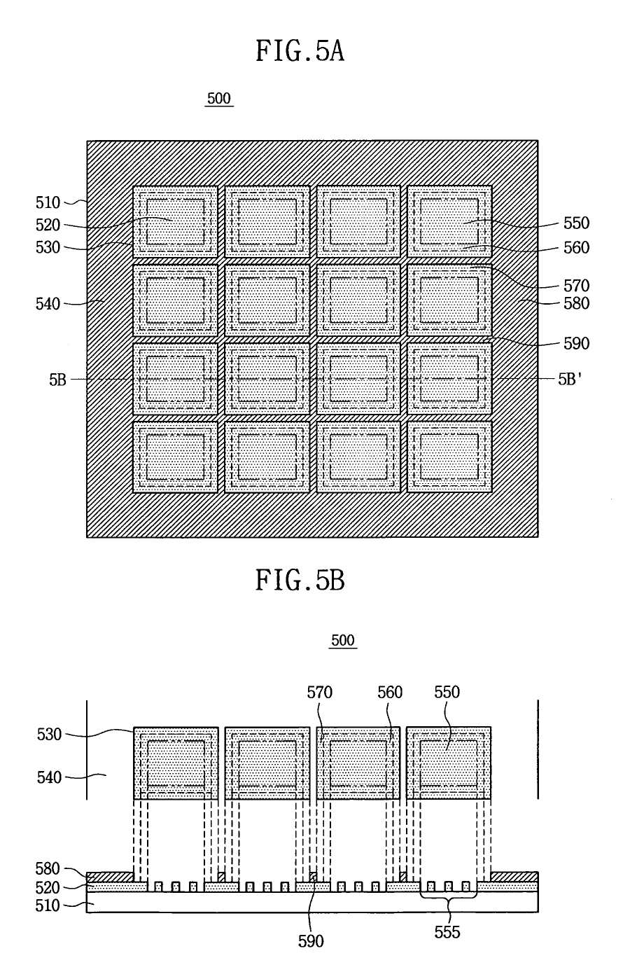

FIG. 5A illustrates plan view of an attenuated phase-shift photomask according to a fifth example embodiment. FIG. 5B illustrates a longitudinal sectional view taken along line 5B-5B′ of FIG. 5A.

Referring to FIGS. 5A and 5B, an attenuated phase-shift photomask 500 according to the fifth example embodiment may include a photomask substrate 510, and a plurality of pattern regions 530 and an opaque region 540 formed on the photomask substrate 510. Each of the pattern regions 530 and the opaque region 540 may include a phase-shift material layer 520, and the opaque region 540 may further include a light opaque pattern layer 580. The pattern region 530 may include at least two cell pattern blocks 550, at least two rim regions 560, and at least two peripheral regions 570. The cell pattern block 550 may include optical patterns 555, which may be formed of a phase-shift material. A block boundary line 590 may be formed between the pattern regions 530. The block boundary line 590 may be positioned on the phase-shift material layer 520 between the pattern regions, and may be formed of a light opaque material. For example, each peripheral region 570 may surround a respective cell pattern block 550, so the block boundary line 590 may be positioned between two adjacent peripheral regions 570. A detailed description of further components in FIGS. 5A and 5B will be understood with reference to FIGS. 1A through 4B and the description of the components of FIGS. 1A through 4B.

Referring to FIG. 5B, the attenuated phase-shift photomask 500 according to the fifth example embodiment may include the photomask substrate 510, the phase-shift material layer 520 formed on the photomask substrate 510, and the light opaque pattern layer 580 formed on the phase-shift material layer 520. The phase-shift material layer 520 may be formed and exposed in the pattern regions 530, and the light opaque pattern layer 580 may be formed between the opaque region 540 and a plurality of rim regions 560. Each of the pattern regions 530 may include at least two cell pattern blocks 550, at least two rim regions 560, and at least two peripheral regions 570. Each of the cell pattern blocks 550 may include the optical patterns 555.

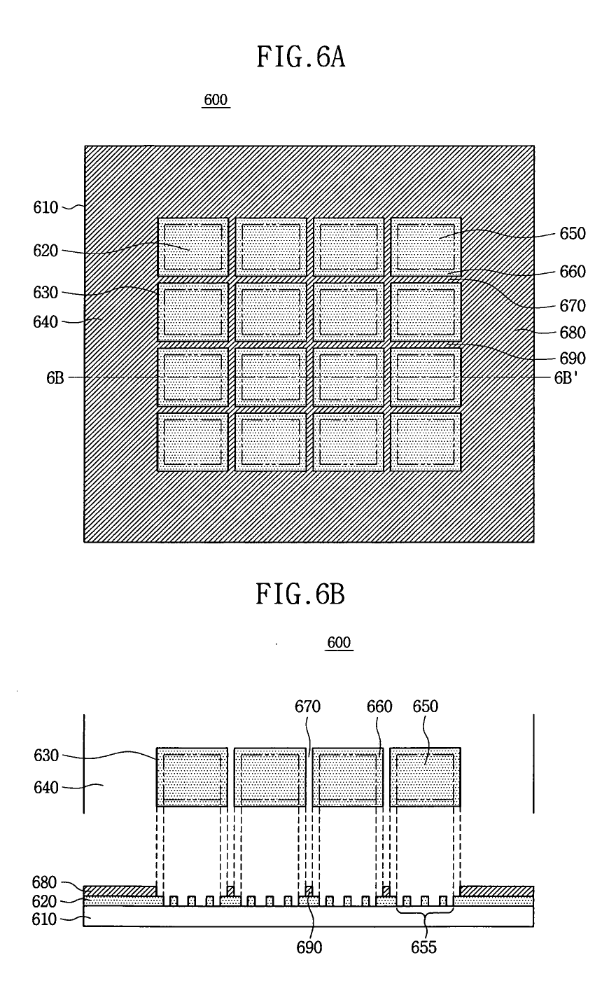

FIG. 6A illustrates a plan view of an attenuated phase-shift photomask according to a sixth example embodiment. FIG. 6B illustrates a longitudinal sectional view taken along line 6B-6B′ of FIG. 6A.

Referring to FIGS. 6A and 6B, an attenuated phase-shift photomask 600 according to the sixth example embodiment may include a photomask substrate 610, and a plurality of pattern regions 630 and an opaque region 640 formed on the photomask substrate 610. The pattern regions 630 and the opaque region 640 may include a phase-shift material layer 620, and the opaque region 640 may further include a light opaque pattern layer 680. Each of the pattern regions 630 may include at least two cell pattern blocks 650, at least two rim regions 660, and at least two peripheral regions 670. Each of the cell pattern blocks 650 may include optical patterns 655, which may be formed of a phase-shift material. A block boundary line 690 may be formed between the pattern regions 630. The block boundary line 690 may be one of light opaque patterns. That is, the block boundary line 690 may be formed of a light opaque material. The block boundary line 690 may be formed in the peripheral region 670 between the pattern regions 630, e.g., the block boundary line 690 may be between two adjacent rim regions 660. The rim region 660 and the opaque region 640 may be in contact with each other, i.e., no peripheral region 670 may be provided between the rim region 660 and the opaque region 640. A detailed description of the remaining components of FIGS. 6A and 6B will be understood with reference to FIGS. 1A through 5B and the description of the components of FIGS. 1A through 5B.

Referring to FIG. 6B, the attenuated phase-shift photomask 600 according to the sixth example embodiment may include the photomask substrate 610, the phase-shift material layer 620 formed on the photomask substrate 610, and the light opaque pattern layer 680 formed on the phase-shift material layer 620. The phase-shift material layer 620 may be formed and exposed in the pattern regions 630, and the light opaque pattern layer 680 may be formed between the opaque region 640 and the pattern regions 630. Each of the pattern regions 630 may include at least two cell pattern blocks 650, at least two rim regions 660, and at least two peripheral regions 670. Each of the cell pattern blocks 650 may include the optical patterns 655. The block boundary line 690 may be formed in the, e.g., entire, peripheral region 670 between the pattern regions 630. No peripheral region may be formed between the rim region 660 and the opaque region 640.

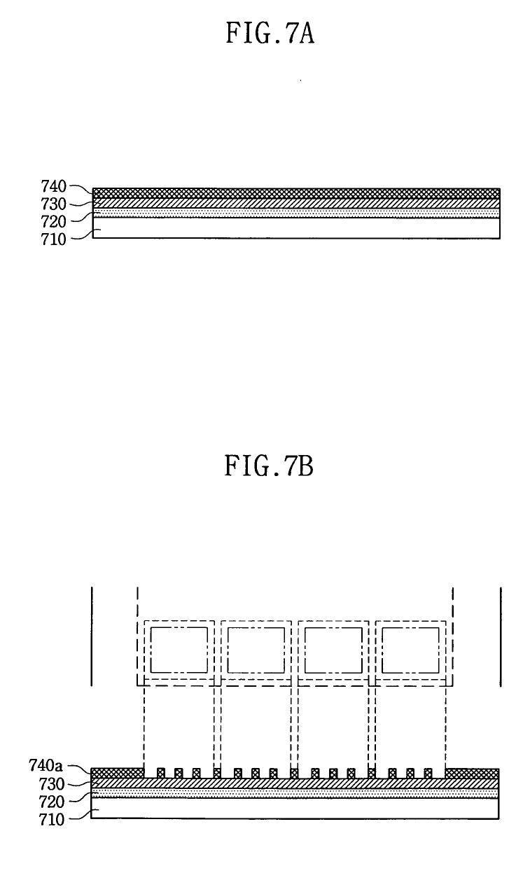

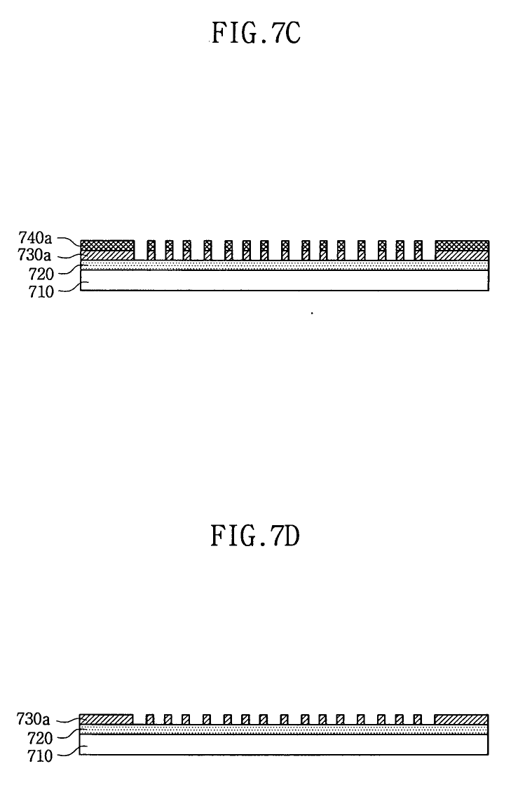

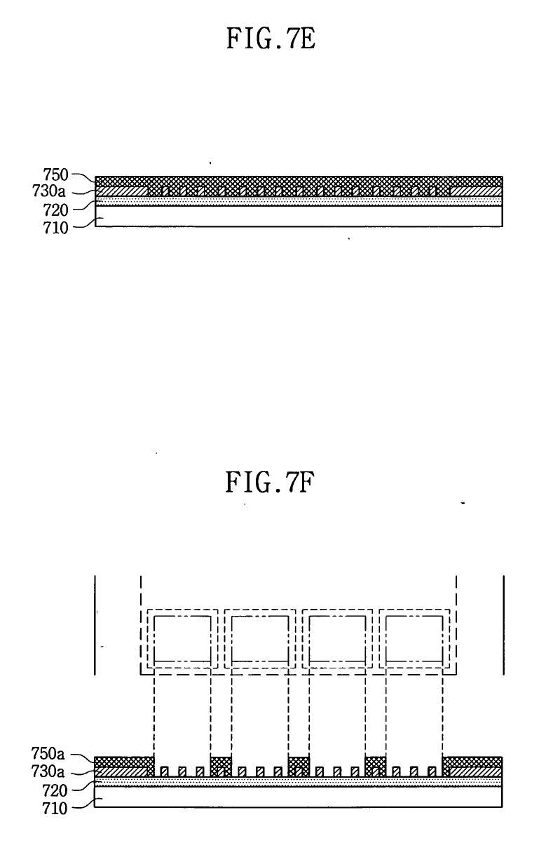

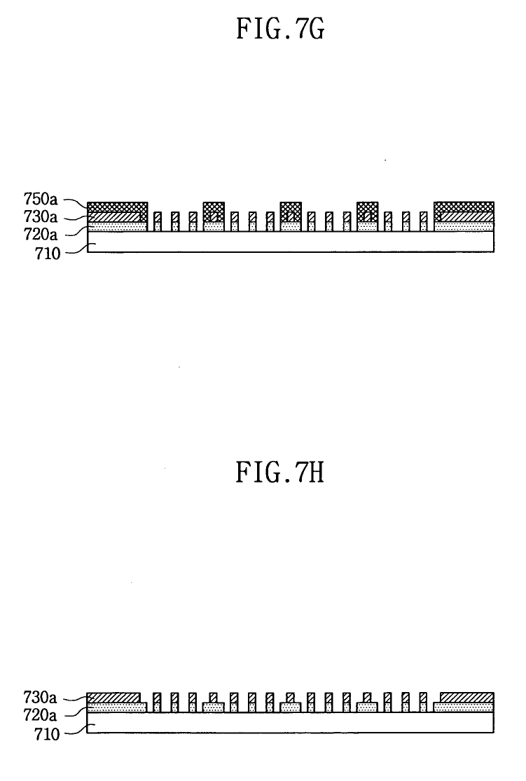

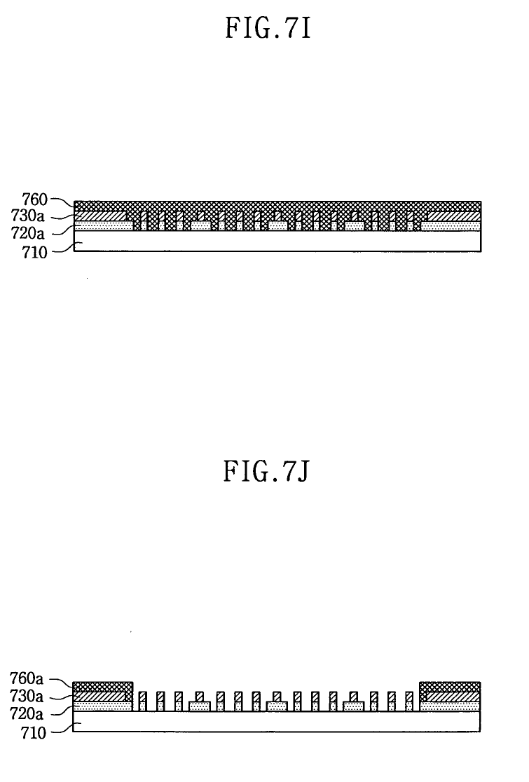

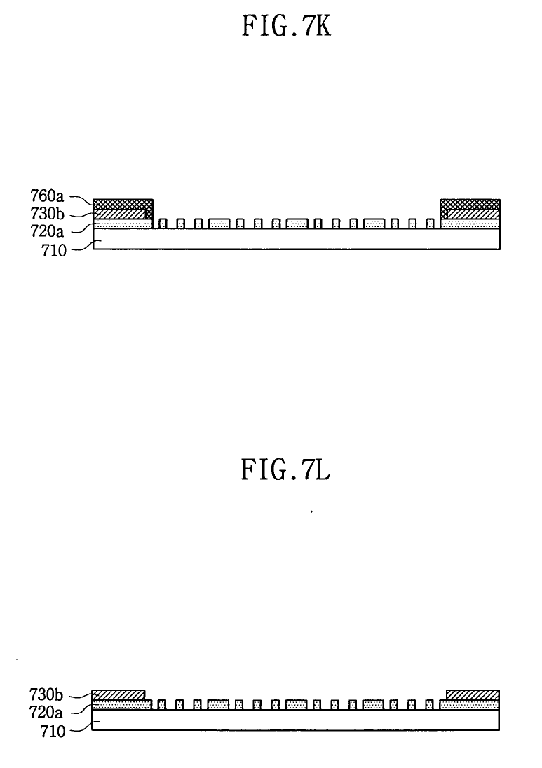

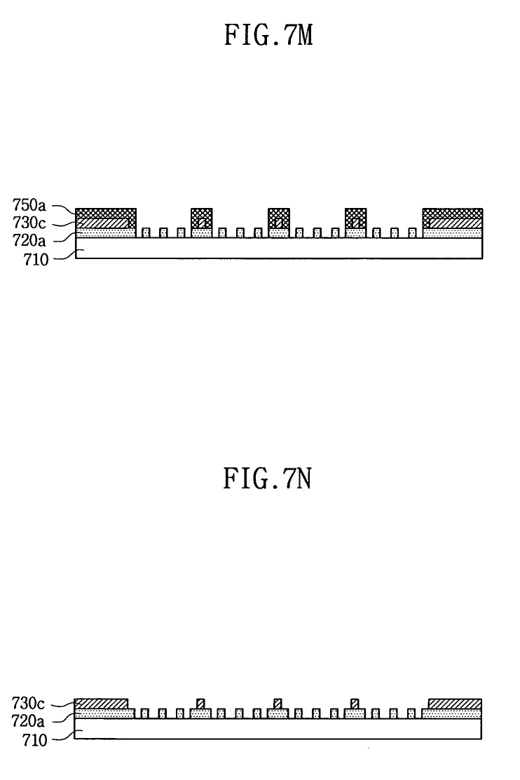

Hereinafter, methods of fabricating attenuated phase-shift photomasks according to various example embodiments will be proposed. FIGS. 7A through 7H illustrate longitudinal sectional views of a method of fabricating an attenuated phase-shift photomask according to example embodiments, FIGS. 7I through 7L illustrate longitudinal sectional views of a method of fabricating an attenuated phase-shift photomask according to modified example embodiments, and FIGS. 7M and 7N illustrate longitudinal sectional views of a method of fabricating an attenuated phase-shift photomask according to other modified example embodiments.

Referring to FIG. 7A, a phase-shift material layer 720, a light opaque material layer 730, and a first resist layer 740 may be formed, e.g., sequentially, on a photomask substrate 710.

The photomask substrate 710 may be formed of a transparent inorganic material, e.g., quartz or glass. The photomask substrate 710 may have a rectangular shape, e.g., with each side having a length of about 6 inches and a width of about 0.635 cm.

The phase-shift material layer 720 may be formed of an inorganic material containing Mo and Si, e.g., a MoSi layer, a MoSiO layer, a MoSiN layer, a MoSiON layer, or an inorganic material containing Mo and Si to which other materials are added. The thickness of the phase-shift material layer 720 may depend on various parameters. For example, the thickness of the phase-shift material layer 720 may be associated with various parameters, e.g., an intrinsic wavelength of light used in a photolithography process, a phase degree to be shifted, a composition of the phase-shift material layer 720, and a thickness of the photomask substrate 710. A method of determining the thickness of the phase-shift material layer 720 is known. The phase-shift material layer 720 may be formed of Mo and Si using a physical or chemical deposition method. By injecting activated oxygen or nitrogen into a reaction chamber, the phase-shift material layer 720 may be formed to have a variety of compositions.

The light opaque material layer 730 may be opaque to light. In the present example embodiments, the light opaque material layer 730 may be formed of, e.g., Cr, Al, Mo, a refractory metal, or an alloy thereof. Like the phase-shift material layer 720, the light opaque material layer 730 may be formed by a physical or chemical deposition method. An anti-reflection layer (ARL) may be further formed on the light opaque material layer 730. However, since the ARL may be patterned in the same shape as the light opaque material layer 730 simultaneously with the light opaque material layer 730 or subsequently after the formation of the light opaque material layer 730, the ARL is not shown for simplicity of drawings. The light opaque material layer 730 may be formed to several thousands of Å, while the ARL may be formed to several hundreds of Å. Since the thicknesses of the light opaque material layer 730 and the ARL may be freely determined, they are not specifically indicated.

The first resist layer 740 may be a photoresist layer or an e-beam resist layer. However, to prevent confusion of terms, the photoresist layer or the e-beam resist layer will now be commonly referred to as a resist layer or a resist pattern. Like the light opaque material layer 730, the thickness of the first resist layer 740 may also be freely determined.

Referring to FIG. 7B, the first resist layer 740 may be exposed to e-beams and developed to form a first resist pattern 740a. It may be understood that the e-beam exposure process includes patterning the first resist layer 740 using e-beams. Subsequently, the exposed first resist layer 740 may be baked and developed, thereby forming the first resist pattern 740a. In the attenuated phase-shift photomasks 100, 200, 300, 400, 500, and 600 according to various example embodiments, the first resist pattern 740a may be formed to expose the cell pattern blocks 150, 250, 350, 450, 550, and 650 and their respective rim regions 160, 260, 360, 460, 560, and 660. However, some of the peripheral regions 170, 270, 370, 470, 570, and 670, e.g., interposed between the rim regions 160, 260, 360, 460, 560, and 660 and respective of the opaque regions 140, 240, 340, 440, 540, and 640, may not be exposed by the first resist pattern 740a. FIG. 7B illustrates an imaginary layout to facilitate the understanding of the technical scope of the present inventive concept.

Referring to FIG. 7C, the light opaque material layer 730 may be etched using the first resist pattern 740a as an etch mask, thereby forming a first light opaque pattern layer 730a. The etching of the light opaque material layer 730 may include activating gases containing carbon (C), fluorine (F), chlorine (Cl), bromine (Br), hydrogen (H), oxygen (O), sulfur (S), or another material into a plasma state. Alternatively, the etching of the light opaque material layer 730 may be performed using a wet etchant containing an acid. By forming the first light opaque pattern layer 730a, the surface of the phase-shift material layer 720 may be selectively exposed.

Referring to FIG. 7D, the first resist pattern 740a may be removed. Since the first resist pattern 740a is formed of an organic material, the removal of the first resist pattern 740a may involve performing an O₂ plasma process or dipping the first resist pattern 740a in an alkali solution. Subsequently, the first light opaque pattern layer 730a and the selectively exposed phase-shift material 720 may be cleansed using a cleaning process.

Referring to FIG. 7E, a second resist layer 750 may be formed on the first light opaque pattern layer 730a. The second resist layer 750 may be formed of the same material as the first resist layer 740.

Referring to FIG. 7F, the second resist layer 750 may be exposed to e-beams and developed to form a second resist pattern 750a. The second resist pattern 750a may be formed using the same processes as the first resist pattern 740a. In the attenuated phase-shift photomask 100, 200, 300, 400, 500, or 600, the third resist pattern 750a may be formed to expose the cell pattern block 150, 250, 350, 450, 550, or 650 and to cover the rim regions 160, 260, 360, 460, 560, or 660.

Referring to FIG. 7G, the phase-shift material layer 720 may be etched using the second resist pattern 750a and/or the first light opaque pattern layer 730a as an etch mask, thereby forming a phase-shift material pattern 720a. The phase-shift material pattern 720a may be formed only in the cell pattern block 150, 250, 350, 450, 550, or 650.

Referring to FIG. 7H, the second resist pattern 750a may be removed. The second resist pattern 750a may be removed by the same method as the first resist pattern 740a. Thereafter, the first light opaque pattern layer 730a may be removed. As a result, the attenuated phase-shift photomask of FIGS. 1A and 1B may be completed.

FIGS. 71 through 7L illustrate longitudinal sectional views of a method of fabricating an attenuated phase-shift photomask according to modified example embodiments.

Referring to FIG. 7I, after the process shown in FIG. 7H, i.e., before the first light opaque pattern layer 730a is removed, a third resist layer 760 may be formed on the entire surface of the resultant structure. The third resist layer 760 may be formed of the same material as the first resist layer 740 or the second resist layer 750.

Referring to FIG. 7J, the third resist layer 760 may be exposed and developed, thereby forming a third resist pattern 760a. The third resist pattern 760a may be formed to cover the first light opaque pattern layer 730a in the opaque regions 140, 240, 340, 440, 540, or 640, and to expose the pattern region 130, 230, 330, 430, 530, or 630.

Referring to FIG. 7K, portions of the first light opaque pattern layer 730a which are exposed in the pattern region 130, 230, 330, 430, 530, or 630 may be removed. Therefore, a second light-opaque pattern layer 730b may be formed only in the opaque region 140, 240, 340, 440, 540, 640. The second light opaque pattern layer 730b may correspond, e.g., to the light opaque pattern layer 280 in FIGS. 2A and 2B.

Referring to FIG. 7L, the third resist pattern 760a may be removed, thereby completing the attenuated phase-shift photomask according to the modified example embodiments.

FIGS. 7M and 7N illustrate longitudinal sectional views of a method of fabricating an attenuated phase-shift photomask according to other modified example embodiments.

Referring to FIG. 7M, after the process shown in FIG. 7G, portions of the first light opaque pattern layer 730a which are exposed in the pattern region 130, 230, 330, 430, 530, or 630 may be removed using the second resist pattern 750a as an etch mask, so that the third light opaque pattern layer 730b may be formed on the opaque region 140, 240, 340, 440, 540, or 640 and the peripheral region 170, 270, 370, 470, 570, or 670.

Referring to FIG. 7N, the second resist pattern 750a may be removed, thereby completing the attenuated phase-shift photomask according to the other modified example embodiments.

The above descriptions of methods of fabricating attenuated phase-shift photomasks are not limited to one of the attenuated phase-shift photomasks of FIGS. 1A through 6B, according to various example embodiments, but may be applied in common or partially to the various example embodiments. Therefore, the above-described and proposed attenuated phase-shift photomasks and methods of fabricating the same may be variously applied to attenuated phase-shift photomasks and methods of fabricating the same according to various other example embodiments.

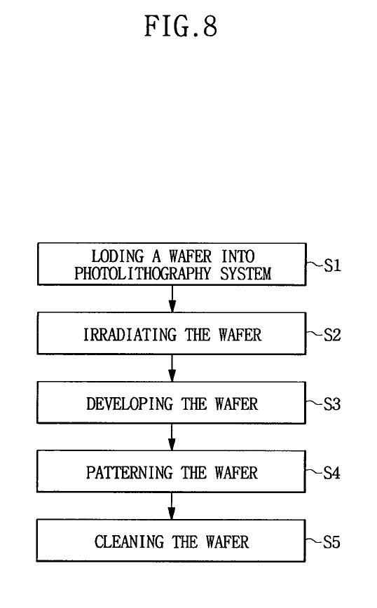

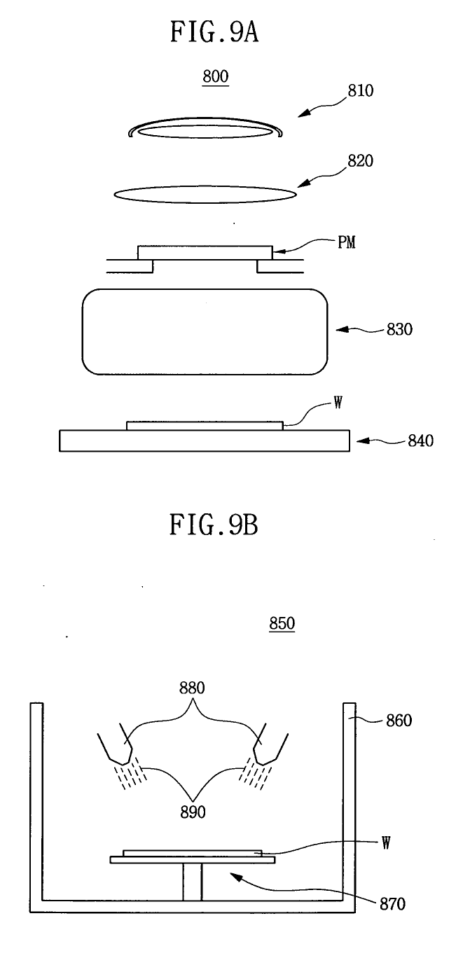

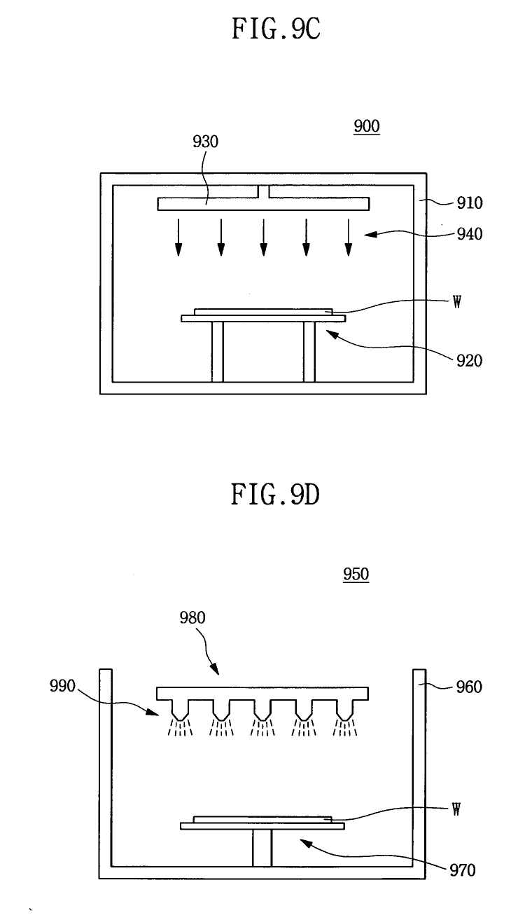

FIG. 8 illustrates a flow chart of steps in a method of fabricating a semiconductor. FIGS. 9A to 9D illustrate processes of fabricating a semiconductor.

Referring to FIGS. 8 and 9A, a wafer W may be loaded into a photolithography system 800 (S1). The photolithography system 800 may include a light source 810, a condenser lens 820, a projection lens 830, and a wafer stage 840. The wafer W may be mounted on the wafer stage 840. The light source 810 may generate UV (Ultra violet) light having a very short wavelength, e.g., i-line, KrF or ArF. The condenser lens 820 may prevent loss of light deviating from the proper light path. The photolithography system 800 may include an attenuated phase-shift photomask PM. In other words, the attenuated phase-shift photomask PM may be loaded in the photolithography system 800. The attenuated phase-shift photomask PM may include optical patterns to be transfer onto the wafer W. The projection lens 830 may transfer the optical patterns from the attenuated phase-shift photomask PM to the wafer W. The wafer W may include a photoresist layer on its own surface.

Again referring to FIGS. 8 and 9A, UV light generated from the light source 810 may irradiate the wafer W passing through the condenser lens 820, the attenuated phase-shift photomask PM, and the projection lens 830 (S2). The optical patterns of the attenuated phase-shift photomask PM may be transferred onto the photoresist layer on the wafer W while being scaled down.

Referring to FIGS. 8 and 9B, the wafer W may be developed (S3). More particularly, the photoresist layer of the wafer W may be developed using a chemical method and formed into a photoresist pattern. This wafer developing process may be carried out in a development apparatus 850. The development apparatus 850 may include a housing 860, a wafer supporter 870, and developing nozzles 880. The wafer supporter 870 may be able to spin. The developing nozzles 880 may spray developing chemicals 890 onto the wafer W.

Referring to FIGS. 8 and 9C, the wafer W may be patterned using the photoresist pattern as a patterning mask (S4). Otherwise, any material layers between the photoresist pattern and the wafer W may be patterned. This patterning process may be carried out in a patterning apparatus 900. The patterning apparatus 900 may include a chamber 910, a wafer chuck 920 to mount the wafer W, and a gas supplier 930 supplying gases 940. The gases 940 may be excited to a plasma state.

Referring to FIGS. 8 and 9D, the photoresist pattern may be removed and cleaned in a cleaning apparatus 950 (S5). The cleaning apparatus 950 may include a tub 960, a wafer mounting table 970, and cleaning nozzles 980. The cleaning nozzles 980 may spray rinse chemicals and/or water 990 onto the wafer W. Then, semiconductors may be fabricated using the photolithography system 800 including the attenuated phase-shift photomask PM.

As described above, an attenuated phase-shift photomask according to example embodiments may have high pattern uniformity. In particular, since optical patterns are highly uniform in an edge portion of a cell pattern block, the yield and productivity of semiconductor chips may be improved, and the performance of semiconductor devices may be stabilized. Also, a semiconductor fabrication process may be simplified. In contrast, a conventional photomask may have non-uniform patterns in an edge portion of a cell pattern block, e.g., due to non-uniformity of etching mask patterns that occur due to a development process.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A method of fabricating an attenuated phase-shift photomask, comprising:
forming a phase-shift material layer on a photomask substrate;
forming a light opaque layer on the phase-shift material layer;
forming a first resist pattern on the light opaque layer to selectively expose a pattern region;
etching the light opaque layer exposed in the pattern region using the first resist pattern as an etch mask, such that a first light opaque pattern layer is formed to selectively expose the phase-shift material layer;
removing the first resist pattern;
forming a second resist pattern on the light opaque layer, the first light opaque pattern layer, and the selectively exposed phase-shift material layer, such that a cell pattern block in the pattern region is selectively exposed;
etching the selectively exposed phase-shift material layer using the first light opaque pattern layer as an etch mask to form a phase-shift material pattern layer selectively exposing a top surface of the photomask substrate; and
removing the second resist pattern.

2. The method as claimed in claim 1, further comprising, after removing the second resist pattern, removing the first light opaque pattern layer from the pattern region to form a second light opaque pattern layer outside the pattern region.

3. The method as claimed in claim 2, wherein forming the second light opaque pattern layer includes:
forming a third resist pattern on the first light opaque pattern layer, such that the pattern region is exposed; and
removing the first light opaque pattern layer exposed in the pattern region using the third resist pattern as an etch mask.

4. The method as claimed in claim 1, further comprising removing the first light opaque pattern layer from the cell pattern block to form a third light opaque pattern layer.

5. The method as claimed in claim 4, wherein removing the first light opaque pattern layer from the cell pattern block includes removing the first light opaque pattern layer exposed in the cell pattern block using the second resist pattern as an etch mask.

6. The method as claimed in claim 1, wherein the pattern region is formed on the photomask substrate to include a rim region surrounding the cell pattern block, the rim region being formed between a boundary line of the pattern region and a boundary line of the cell pattern block to surround the cell pattern block in a rim type.

7. The method as claimed in claim 6, wherein:
etching the light opaque layer includes removing portions of the light opaque layer from the rim region to expose the phase-shift material layer, and
forming the second resist pattern includes covering the phase-shift material layer in the rim region, such that the rim region includes the phase-shift material pattern layer.

8. The method as claimed in claim 6, wherein the rim region is formed to have a width of about 200 μm to about 500 μm.

9. The method as claimed in claim 1, further comprising:
forming a resist pattern exposing a peripheral region, the peripheral region being in the pattern region and having a boundary line between a boundary line of the pattern region and a boundary line of the cell pattern block; and
removing the first light opaque pattern layer from the peripheral region.

10. A method of fabricating a semiconductor, comprising:
loading a wafer into a photolithography system having an attenuated phase-shift photomask, the wafer having a material layer and a photoresist layer thereon;
irradiating the photoresist layer using UV light;
developing the photoresist layer to form a photoresist pattern;
patterning the material layer to form a material pattern using the photoresist pattern as a patterning mask;
removing the photoresist pattern; and
cleaning the wafer,
wherein the attenuated phase-shift photomask is fabricated by a method including:
forming a phase-shift material layer on a photomask substrate,
forming a light opaque layer on the phase-shift material layer,
forming a first resist pattern on the light opaque layer to selectively expose a pattern region,
etching the light opaque layer exposed in the pattern region using the first resist pattern as an etch mask, such that a first light opaque pattern layer is formed to selectively expose the phase-shift material layer,
removing the first resist pattern,
forming a second resist pattern on the light opaque layer, the first light opaque pattern layer, and the selectively exposed phase-shift material layer, such that a cell pattern block in the pattern region is selectively exposed,
etching the selectively exposed phase-shift material layer using the first light opaque pattern layer as an etch mask to form a phase-shift material pattern layer selectively exposing a top surface of the photomask substrate, and
removing the second resist pattern.

11. (canceled)

12. An attenuated phase-shift photomask, comprising:
a phase-shift pattern layer disposed on a photomask substrate,
wherein the phase-shift pattern layer includes a pattern region and an opaque region at an edge of the pattern region, the pattern region including a cell pattern block having optical patterns, a rim region surrounding the cell pattern block in a rim type, and a peripheral region surrounding the rim region, and
wherein the rim region does not include optical patterns.

13. The attenuated phase-shift photomask as claimed in claim 12, wherein the optical patterns are only in the cell pattern block of the phase-shift pattern layer.

14. The attenuated phase-shift photomask as claimed in claim 12, further comprising a light opaque pattern layer in the opaque region.

15. The attenuated phase-shift photomask as claimed in claim 14, wherein the cell pattern block and the rim region do not include the light opaque pattern layer.

16. The attenuated phase-shift photomask as claimed in claim 12, wherein the rim region has a width of about 200 μm to about 500 μm.

17. The attenuated phase-shift photomask as claimed in claim 12, wherein the peripheral region selectively includes a portion of the light opaque pattern layer.
